(19) United States
(12) Patent Application Publication
(10) Pub. No.: US 2007/0015089 A1
(43) Pub. Date: Jan. 18, 2007

(54) Method of making a semiconductor device using a dual-tone phase shift mask

(75) Inventors: Richard D. Peters, Austin, TX (US); Bernard J. Roman, Austin, TX (US); James R. Wasson, Austin, TX (US)

Correspondence Address: FORTKORT GRETHER & KELTON LLP, 8911 N. CAPITAL OF TEXAS HWY., SUITE 3200, AUSTIN, TX, 78759, US

(73) Assignee: Freescale Semiconductor, Inc.

(21) Appl. No.: 11/181,168

(22) Filed: Jul. 14, 2005

(51) Int. Cl. G03F 7/26

(52) U.S. Cl. 430/313; 430/311

(57) ABSTRACT

A method for making a semiconductor device is provided which comprises (a) providing a source of actinic radiation (601), (b) providing a reticle comprising (i) a substrate having a plurality of structures defined therein, said substrate being essentially transparent to the actinic radiation, and (ii) a layer of attenuating material disposed over at least some of said plurality of structures, wherein the layer of attenuating material has a transmission with respect to the actinic radiation that is within the range of about 5% to about 50%, and wherein the combination of the layer of attenuating material and the substrate imparts to the actinic radiation a phase change within the range of about 165° to about 225° (603), and (c) utilizing the reticle and the source of actinic radiation to impart a pattern to a semiconductor substrate (607, 609).

### FIELD OF THE DISCLOSURE

The present disclosure relates generally to phase shifting masks, and more particularly to photomasks useful in chromeless phase lithography (CPL) applications.

### BACKGROUND OF THE DISCLOSURE

As a result of innovations in integrated circuit and packaging fabrication processes, dramatic performance improvements and cost reductions have been obtained in the electronics industry. The speed and performance of chips, and hence the computer systems that utilize them, are ultimately dictated by the minimum printable features sizes obtainable through lithography. The lithographic process, which replicates patterns rapidly from one wafer or substrate to another, also determines the throughput and the cost of electronic systems. A typical lithographic system includes exposure tools, masks, resist, and all of the processing steps required to transfer a pattern from a mask to a resist, and then to devices.

Chromeless phase lithography (CPL) is a particular lithographic technique that utilizes chromeless mask features to define circuit features with pairs of 0-degree and 180-degree phase steps. These phase steps can be obtained, for example, by etching a trench in a quartz substrate to a depth corresponding to a 180-degree phase shift at the illumination wavelength (that is, the wavelength of the actinic radiation) of the lithography system. Alternatively, phase shift layers can be formed as mesas on a quartz substrate.

CPL mask designs can be created by assigning circuit features to different zones or groups, based on the physical attributes of those features. One example of such a system which is known in the art is depicted in FIGS. 1-2. The system illustrated therein utilizes three such zones. In that system, circuit features having widths of 90 nm or less are assigned to Zone 1. These features are constructed with 100% transmission phase-shifted structures and are printed utilizing adjacent phase edges. Hence, these features are chromeless features. Features having a width greater than 130 nm are deemed to reside in Zone 3, and are printed utilizing chrome. Features having widths between 90 nm and 130 nm are deemed to reside in Zone 2. The features of Zone 2 are too wide to be defined using the 100% transmission of pure CPL and are too narrow to be printed solely in chrome, and hence are printed using a so-called “zebra” pattern treatment. The zebra pattern treatment employs a plurality of chrome patches which are formed on the chromeless feature pattern to be imaged. Such patches are intended to reduce the average optical transmission of the otherwise chromeless feature. If correctly defined on the mask, the zebra pattern treatment can result in improved lithographic margins for features that reside in Zone 2 compared to either chromeless or chrome features.

While CPL processes of the type depicted in FIGS. 1-2 have some desirable attributes, the zebra pattern treatment step utilized in these processes involves structures that are sub-resolution. Moreover, since the zebra structures are secondary features formed in the second writing step which typically involves use of an optical pattern generator (the first writing step being an electron beam pattern generator used to form the primary, chromeless features), they must be registered with the primary features. Consequently, the mask utilized to form these structures is difficult to fabricate. The zebra structures also significantly increase the size of the pre- and post-fracture database. Moreover, critical dimension (CD) uniformity and control on zebra structures has proven to be less than desirable.

Other phase shifting masks are also known in the art that are somewhat similar to the mask described above. For example, FIG. 3 illustrates a prior art mask 101 that comprises a quartz substrate 103 having a plurality of 30% transmission features 105 disposed thereon. Each feature 105 comprises a 40 Å thick layer of chrome 107 with a 910 Å thick layer of SiON 109 disposed thereon. Masks of this type have been proposed as stand-alone solutions for so-called “high transmission” attenuated phase shifting masks, with no regions rendered as CPL. Such a mask has proven difficult to fabricate, however. In particular, it has proven challenging to remove portions of the layer of chromium 107 (as is necessary to pattern the mask from a blank) without etching the underlying quartz substrate, due to the proximity of the two.

There is thus a need in the art for a CPL mask design, and a process for making the same, that overcomes the aforementioned infirmities. In particular, there is a need in the art for a method for simplifying the fabrication of CPL masks, particularly those for Zone 2 features. There is also a need in the art for masks made by such a method. These and other needs are met by the devices and methodologies described herein.

### BRIEF DESCRIPTION OF THE DRAWINGS

FIG. 1 is a graph of wafer critical dimensions as a function of mask critical dimensions for a prior art CPL process;

FIG. 2 is an illustration of a prior art 3-zone CPL process;

FIG. 3 is an illustration of a portion of a prior art mask;

FIG. 4 is an illustration of a mask with a chrome portion, a CPL portion, and a 30% transmission portion;

FIG. 5 is an illustration of one step in a prior art method for fabricating a mask in accordance with the teachings herein;

FIG. 6 is an illustration of one step in a prior art method for fabricating a mask in accordance with the teachings herein;

FIG. 7 is an illustration of one step in a prior art method for fabricating a mask in accordance with the teachings herein;

FIG. 8 is an illustration of one step in a prior art method for fabricating a mask in accordance with the teachings herein;

FIG. 9 is an illustration of one step in a prior art method for fabricating a mask in accordance with the teachings herein;

FIG. 10 is an illustration of one step in a prior art method for fabricating a mask in accordance with the teachings herein;

FIG. 11 is an illustration of one step in a prior art method for fabricating a mask in accordance with the teachings herein;

FIG. 12 is an illustration of one step in a first embodiment of a method for fabricating a mask in accordance with the teachings herein;

FIG. 13 is an illustration of one step in a first embodiment of a method for fabricating a mask in accordance with the teachings herein;

FIG. 14 is an illustration of one step in a first embodiment of a method for fabricating a mask in accordance with the teachings herein;

FIG. 15 is an illustration of one step in a first embodiment of a method for fabricating a mask in accordance with the teachings herein;

FIG. 16 is an illustration of one step in a first embodiment of a method for fabricating a mask in accordance with the teachings herein;

FIG. 17 is an illustration of one step in a first embodiment of a method for fabricating a mask in accordance with the teachings herein;

FIG. 18 is an illustration of one step in a first embodiment of a method for fabricating a mask in accordance with the teachings herein;

FIG. 19 is an illustration of one step in a first embodiment of a method for fabricating a mask in accordance with the teachings herein;

FIG. 20 is an illustration of one step in a first embodiment of a method for fabricating a mask in accordance with the teachings herein; and

FIG. 21 is an illustration of one step in a second embodiment of a method for fabricating a mask in accordance with the teachings herein;

FIG. 22 is an illustration of one step in a second embodiment of a method for fabricating a mask in accordance with the teachings herein;

FIG. 23 is an illustration of one step in a second embodiment of a method for fabricating a mask in accordance with the teachings herein;

FIG. 24 is an illustration of one step in a second embodiment of a method for fabricating a mask in accordance with the teachings herein;

FIG. 25 is an illustration of one step in a second embodiment of a method for fabricating a mask in accordance with the teachings herein;

FIG. 26 is an illustration of one step in a second embodiment of a method for fabricating a mask in accordance with the teachings herein;

FIG. 27 is an illustration of one step in a second embodiment of a method for fabricating a mask in accordance with the teachings herein;

FIG. 28 is an illustration of one step in a second embodiment of a method for fabricating a mask in accordance with the teachings herein;

FIG. 29 is an illustration of one step in a second embodiment of a method for fabricating a mask in accordance with the teachings herein;

FIG. 30 is a graph of CD variation as a function of pitch for CDs of 60 nm;

FIG. 31 is a graph of CD variation as a function of pitch for CDs of 70 nm;

FIG. 32 is a graph of field amplitude versus wavelength; and

FIG. 33 is a flowchart of one embodiment of fabricating a semiconductor device in accordance with the teachings herein.

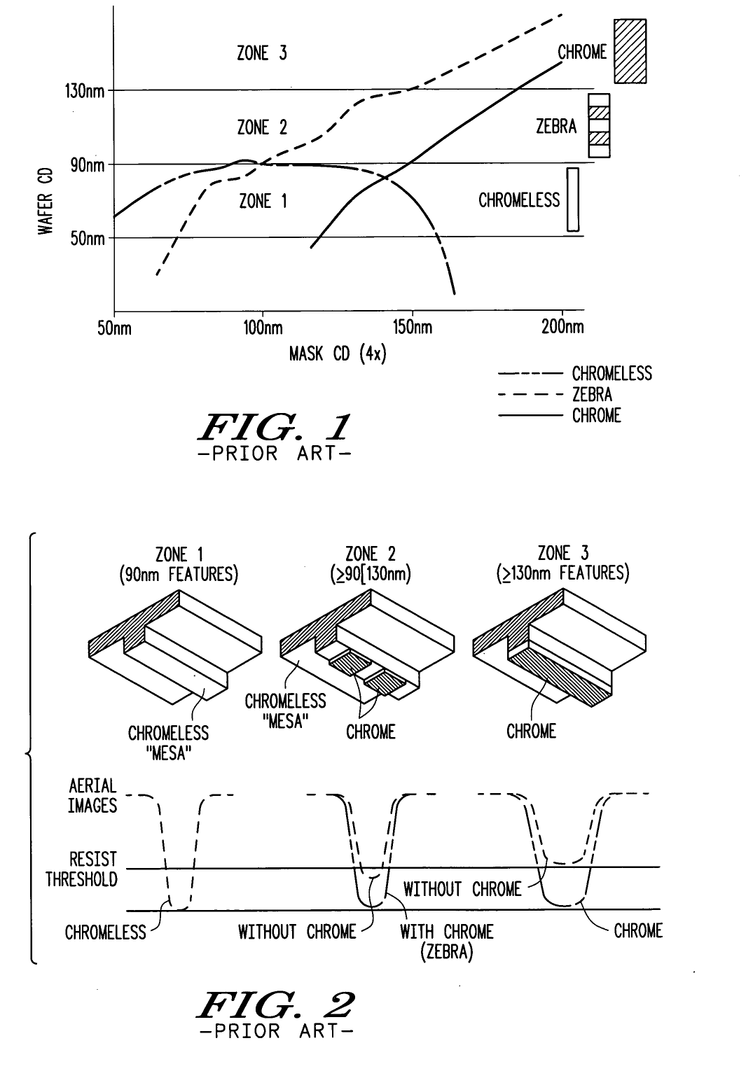

### DETAILED DESCRIPTION

In one aspect, a method for making a semiconductor device is provided which comprises (a) providing a source of actinic radiation; (b) providing a reticle comprising (i) a substrate having a plurality of structures defined therein, said substrate being essentially transparent to the actinic radiation, and (ii) a layer of attenuating material disposed over at least some of said plurality of structures, wherein the layer of attenuating material has a transmission with respect to the actinic radiation that is within the range of about 5% to about 50%, and wherein the combination of the layer of attenuating material and the substrate imparts to the actinic radiation a phase change within the range of about 165° to about 225°; and (c) utilizing the reticle and the source of actinic radiation to impart a pattern to a semiconductor substrate. The layer of attenuating material may be a unitary layer.

In another aspect, a method for making a semiconductor device is provided which comprises (a) providing a source of actinic radiation; (b) providing a reticle comprising (i) a first set of reticle features adapted to produce device features having a critical dimension CD within the range of 0<k≧CD<m, (ii) a second set of reticle features adapted to produce device features having a critical dimension CD<k, and (iii) a third set of reticle features adapted to produce device features having a critical dimension CD≧m, where k and m are real number dimensions, and wherein each of the second set of reticle features comprises a quartz mesa capped with a layer of attenuating material; and (c) utilizing the reticle and the source of actinic radiation to impart a pattern to a semiconductor substrate.

In a further aspect, a reticle is provided in combination with a source of actinic radiation. The reticle comprises (a) a substrate having a plurality of structures defined therein, said substrate being essentially transparent to the actinic radiation, and (b) a layer of attenuating material disposed over at least some of said structures; wherein the layer of attenuating material has a transmission within the range of about 5% to about 50%, and wherein the combination of the layer of attenuating material and substrate imparts to the attenuating radiation a phase change within the range of about 150 degrees to about 210 degrees.

In still another aspect, a method for making a reticle is provided. In accordance with the method, a blank is provided which comprises an essentially transparent substrate, a layer of an attenuating material, a layer of opaque material, and a first layer of photoresist. The first layer of photoresist is patterned with first and second sets of features, and is used as an etch mask to impart the first and second sets of features to the layer of opaque material and the layer of attenuating material.

These and other aspects of the present disclosure are described in greater detail below.

It has now been found that attenuated etched quartz features (that is, features that reduce the transmission of the underlying substrate, without rendering it entirely opaque) can be used to replace chrome zebra structures on a CPL mask. The attenuated features, which may be, for example, Ta-capped etched quartz features, are easier to manufacture because, unlike the zebra structures known in the art, they do not require sub-resolution components. Moreover, the attenuated features provide better CD control than chromium zebra structures in many situations. In addition, the attenuated features can be configured with appropriate phase difference and transmission (e.g., 30%) characteristics, and can be combined on the same reticle with pure CPL features having 100% transmission and/or with opaque (e.g., chrome) features.

FIG. 4 illustrates one particular, non-limiting embodiment of a photolithographic mask made in accordance with the teachings herein. The mask 201 comprises a substrate 203 with Zone 1 structures 205, Zone 2 structures 207 and Zone 3 structures 209 defined thereon. The Zone 1 structures 205 are etched quartz features which comprise a plurality of quartz mesas 211. The Zone 2 structures 207 are 30% transmission structures with a 180° phase shift which comprise a plurality of quartz mesas 211 that are capped with a 90 Å thick layer of tantalum 213 as an attenuating material. The Zone 3 structures 209 are essentially 0% transmission structures which comprise a plurality of quartz mesas 211 capped with an opaque material 215 (in the particular embodiment depicted, the opaque material is a 500 Å thick layer of chrome). In the structures of each of the three zones, the quartz mesas 211 are formed by etching trenches 217 into the quartz substrate 203 to a depth of about 1904 Å. Of course, one skilled in the art will appreciate that the appropriate etch depth is dependent on the optical properties desired and the source of actinic radiation, and may vary from one application to another.

Various modifications and substitutions may be made to the particular embodiment described above without departing from the scope of the teachings herein. For example, while this particular embodiment employs tantalum as the attenuating material, it will be appreciated that various other attenuating materials may also be used, including, but not limited to, tantalum nitride, tantalum silicon nitride, titanium, hafnium, and various mixtures or alloys of the foregoing. In most cases, the thickness of these attenuating materials will be less than about 200 Å.

In some embodiments, the attenuating material may comprise a plurality of materials. For example, in some embodiments, the attenuating material may be present as a multilayer structure comprising two or more diverse materials. If one of the two diverse materials is a metal, the other material may be, for example, an oxide, nitride, or other compound or salt of that metal. As a specific example, tantalum is found to readily form an oxide on the surface thereof (typically to a thickness of about 15 Å). This oxide layer serves as a convenient barrier layer to many chrome etch processes, and does not significantly effect the near field optical properties of the tantalum layer. It will be appreciated, of course, that other metals and their oxides could perform a similar role. In embodiments where the presence of such an oxide layer is desired but does not occur naturally, a separate oxidation step, using hydrogen peroxide or another suitable oxidizing agent, may be employed.

The particular attenuating material used, and the thickness of that material, may vary from one application to another. Preferably, however, the choice of attenuating material, and the layer thickness of that material, will be selected to provide an optical transmission of the actinic radiation through the layer of about 5% to about 50%, more preferably about 15 to about 40%, and most preferably about 25% to about 35%. The choice of attenuating material, and the layer thickness of that material, will also preferably be selected to provide the attenuating structure (and any trenches or mesas which form a part thereof) with the ability to impart to the actinic radiation a phase change of about 165° degrees to about 225°, more preferably of about 175° to about 215°, even more preferably of about 185° to about 205°, and most preferably of about 195°.

Preferably, the phase change associated with the attenuating features is imparted primarily by the substrate (and any trenches or mesas defined therein), and even more preferably is provided essentially exclusively by the substrate. However, embodiments are also contemplated wherein the attenuating material itself provides an additional phase change, or provides most or all of the phase change. It will be appreciated, of course, that these phase change and transmission properties depend on the indices of refraction (and more particularly, the differences in index of refraction) and extinction coefficients of the attenuating material and/or the substrate, and hence could also be described in terms of these parameters. The phase change and transmission properties associated with a given set of indices of refraction and extinction coefficients may be determined, for example, through suitable simulations and/or calculations.

The use of chrome in the embodiment described above is advantageous in that chrome has a very low optical transmission (i.e., a very high opacity) with respect to 193 nm wavelengths and other commonly used sources of actinic radiation, even at fairly thin layer thicknesses, and hence functions well in Zone 3 structures. Moreover, a number of metal etchants are available that exhibit good selectivity between chrome and the contemplated attenuating materials. This allows chrome to function efficiently as an etch mask for tantalum and other materials that may be used as the attenuating material in Zone 2 structures, and also allows chrome to be selectively removed from the attenuating material in areas of the mask where its presence is not desired. However, it will be appreciated that other materials, or combinations of materials, that provide these functionalities may be used in place of chrome and/or in conjunction with the attenuating material, including, but not limited to, titanium and tungsten, and various combinations, mixtures, salts, compounds, or alloys of the foregoing. Moreover, in some embodiments, a first material with the requisite opacity may be used in conjunction with a second material that can function as a suitable etch mask.

In some embodiments of the devices made in accordance with the teachings herein, one or more stress compensation layers may be provided between the opaque material and the substrate, the attenuating material and the substrate, or between the opaque material and the attenuating layer. Such stress compensation layers may comprise, for example, silicon oxynitride or other suitable stress compensating materials as are known to the art. Likewise, various barrier layers may be used in the structures described herein to impart etch selectivity to various layers, or for other purposes.

Unless otherwise specified, the embodiments described herein assume actinic radiation having a wavelength of 193 nm. It will be appreciated, however, that the teachings herein are not limited to a specific wavelength of actinic radiation. Moreover, one skilled in the art will appreciate that the structures and methodologies described herein could be adapted to operate at more than one wavelength of actinic radiation. For example, embodiments are contemplated herein in which the opaque layer and attenuating layer are adapted to operate at both 193 nm and 248 nm. This would allow blanks to be provided that work at multiple wavelengths of commonly used actinic radiation, thus allowing the end user to optimize the device for a particular wavelength through control of etch depth or other parameters.

The reticles described herein can be fabricated by a number of methods. The preferred method for fabricating such reticles, which is described below, can be better understood by contrasting it with the prior art mask fabrication process flow illustrated in FIGS. 5-11.

With reference to FIG. 5, a mask blank 301 is provided which comprises a quartz substrate 303, a layer of chrome 305, an antireflective layer 307, and a first layer of photoresist 309. Then, as shown in FIG. 6, the first layer of photoresist 309 is patterned through suitable photolithographic techniques to create a pattern therein corresponding to the etched quartz features of the chromeless Zone 1 features and the chrome zebra Zone 2 features. The antireflective layer 307 and the underlying chrome layer 305 are subsequently etched down to the substrate 303 through the use of a suitable etchant as shown in FIG. 7.

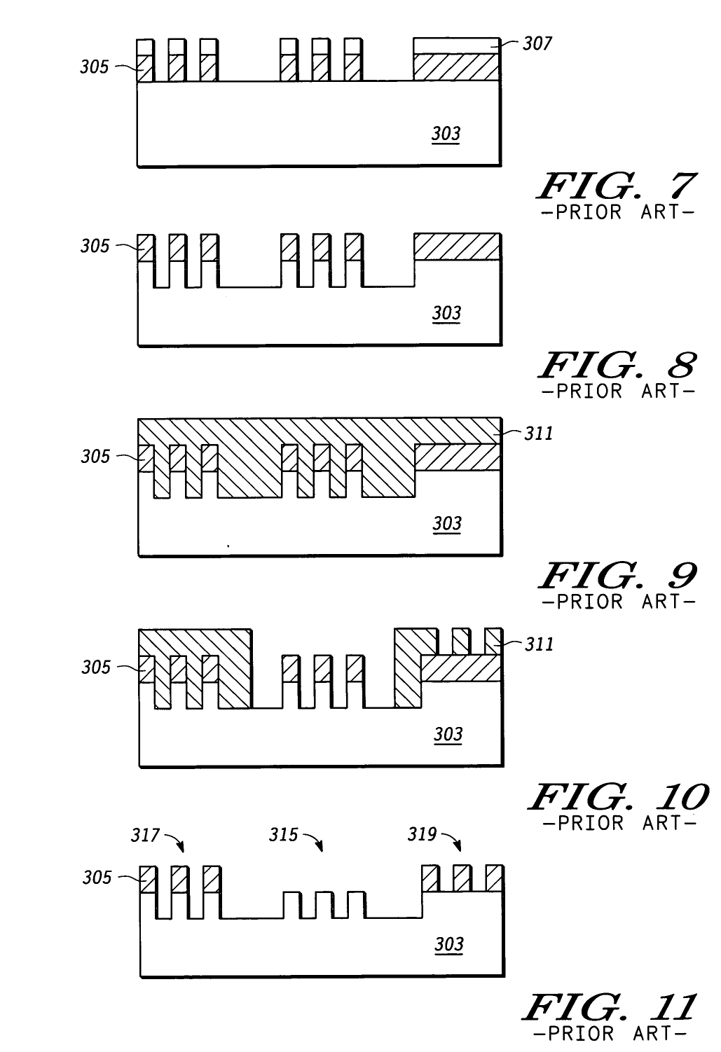

The substrate is subsequently etched using the antireflective layer 307 and the chrome layer 305 as etch masks as shown in FIG. 8. This imparts a first pattern 310 to the quartz substrate 303 which corresponds to the chromeless phase components of the Zone 1 features 315 and the chrome zebra components of the Zone 2 features 317. The antireflective layer 307 is usually removed during the quartz substrate etch.

With reference to FIG. 9, a second layer of photoresist 311 is deposited over the structure. As shown in FIG. 10, the second layer of photoresist 311 is then imparted with a pattern for the chrome zebra Zone 2 features and the chrome binary Zone 3 features, and the portion of the second layer of photoresist 311 extending over the Zone 1 features 315 is removed. The pattern for the chrome zebra Zone 2 features 317 and the chrome binary Zone 3 features 319 is then imparted to the exposed portion of the metal layer 305 through etching (this etching also removes the metal layer 305 from the Zone 1 features 315). The second layer of photoresist is subsequently stripped, thus yielding the structure shown in FIG. 11.

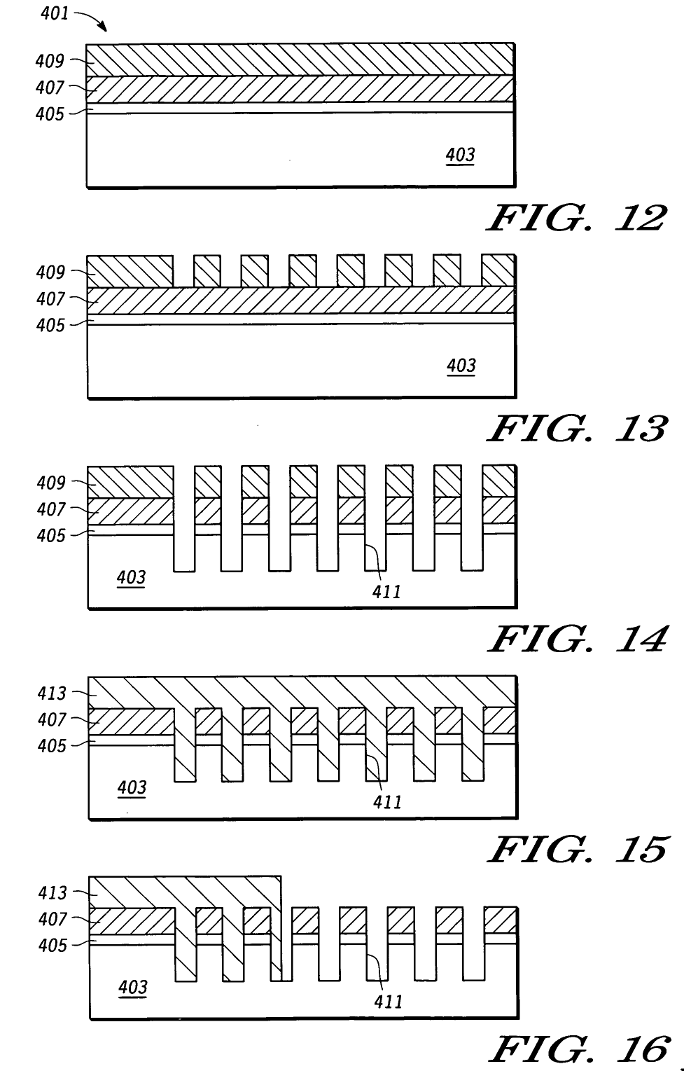

FIGS. 12-20 illustrate a first specific, non-limiting embodiment of a mask fabrication process flow in accordance with the teachings herein. With reference to FIG. 12, a mask blank 401 is provided which comprises a quartz substrate 403, a layer of tantalum 405 as the attenuating material, a layer of chrome 407 as the opaque material, and a first layer of photoresist 409. The first layer of photoresist 409 is exposed and patterned as shown in FIG. 13 using a critical e-beam write process, and is used as an etch mask to etch the layer of tantalum 405, the layer of chrome 407, and the quartz substrate 403. The etch process results in the creation of a series of 180° phase-shifting quartz mesas 411 in the substrate 403 as shown in FIG. 14.

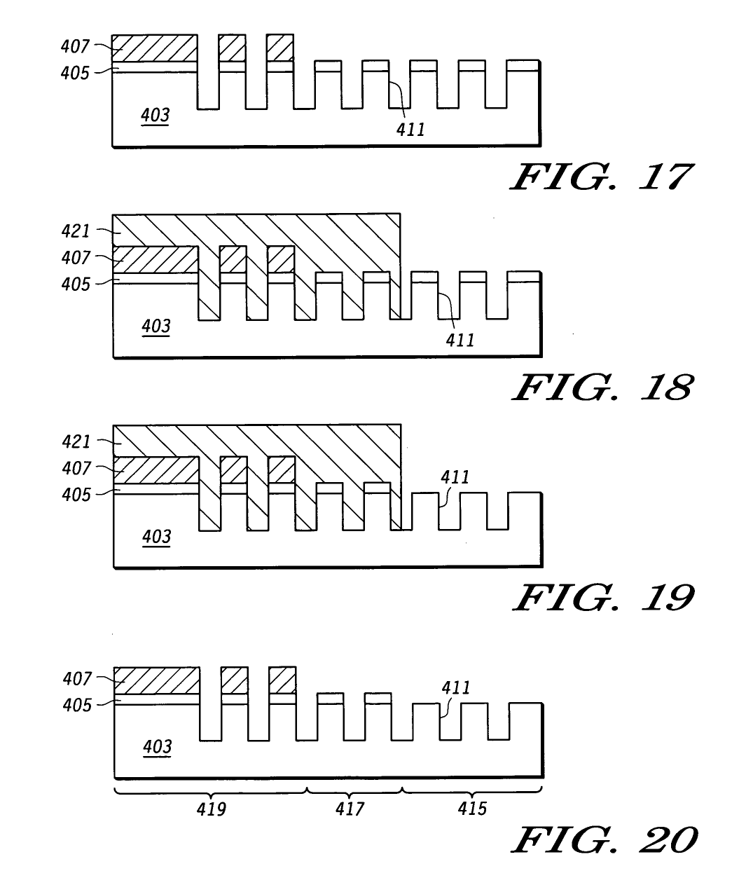

The first layer of photoresist 409 is then stripped, and a second layer of photoresist 413 is deposited over the structure as shown in FIG. 15. As shown in FIG. 16, the portion of the second layer of photoresist 413 that extends over the Zone 1 features 415 and the Zone 2 features 417 (see FIG. 20) is removed. The chrome layer 407 is then removed from the exposed portion of the mask through etching and the second layer of photoresist 413 is stripped, thus resulting in the structure depicted in FIG. 17.

A third layer of photoresist 421 is then deposited over the structure as shown in FIG. 18, and is patterned to expose the Zone 1 features 415 (see FIG. 20). The tantalum layer 405 is then removed from the exposed portion of the mask with a suitable etchant as shown in FIG. 19, and the third layer of photoresist 421 is stripped, thus yielding the structure depicted in FIG. 20. In the resulting mask, the Zone 1 features 415 are pure quartz CPL structures with essentially 100% transmission, and the Zone 2 features 417 are tantalum-capped phase shifting quartz structures with 30% transmission. The Zone 3 structures 419 are essentially opaque (0% transmission) chrome-capped structures.

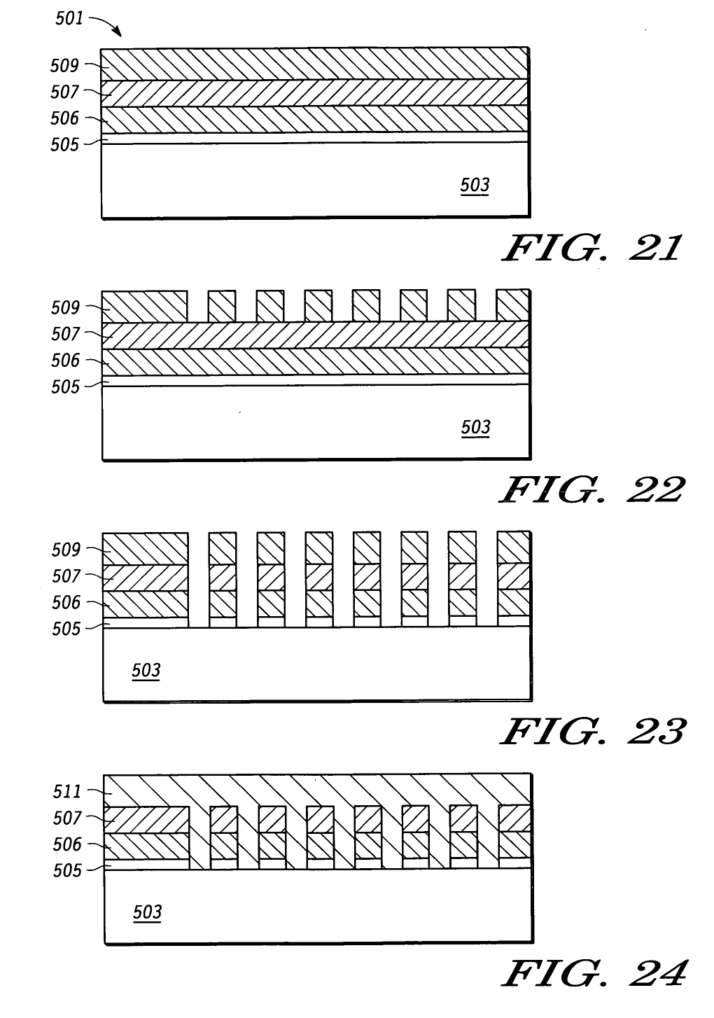

FIGS. 21-29 illustrate a second specific, non-limiting embodiment of a mask fabrication process flow in accordance with the teachings herein. With reference to FIG. 21, a mask blank 501 is provided which comprises a quartz substrate 503, a layer of tantalum 505 as the attenuating material, a layer of phase-shifting material 506, a layer of chrome 507 as the opaque material, and a first layer of photoresist 509. The layer of phase-shifting material 506 in this particular embodiment comprises silicon oxynitride (SiON) and imparts a phase shift of 180° to the actinic radiation.

The first layer of photoresist 509 is exposed and patterned as shown in FIG. 22 using a critical e-beam write process, and is used as an etch mask to etch the layer of tantalum 505, the layer of phase-shifting material 506, and the layer of chrome 507 as shown in FIG. 23. The first layer of photoresist 509 is then stripped, and a second layer of photoresist 511 is deposited over the structure as shown in FIG. 24.

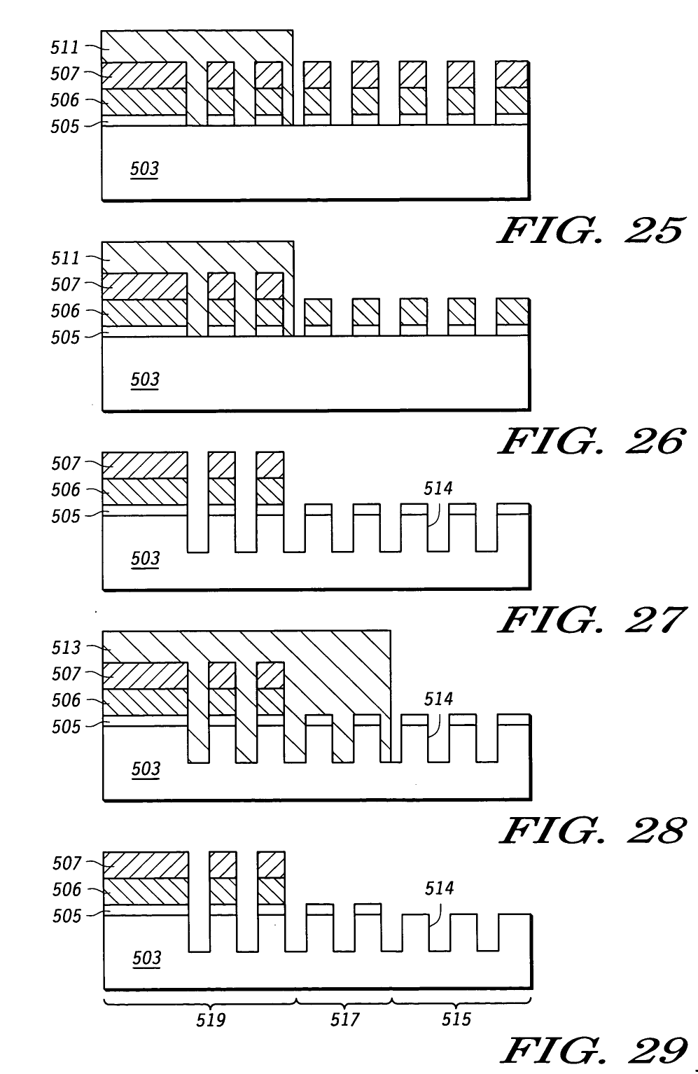

As shown in FIG. 25, the second layer of photoresist 511 is removed from the portion of the mask structure where the layer of chrome 507 is to be removed. The layer of chrome 507 is subsequently removed from the exposed portion of the mask by etching as shown in FIG. 26.

As shown in FIG. 27, the second layer of photoresist 511 is then stripped, and the exposed portion of the phase-shifting layer 506 is removed from the structure. The quartz substrate 503 is also etched. The substrate etch may be accomplished by the same etch used to remove the exposed portion of the phase-shifting layer 506, or may be accomplished through a separate etch, and results in the creation of a series of 180° phase-shifting quartz mesas 514 in the substrate 503.

With reference to FIG. 28, a third layer of photoresist 513 is then deposited over the mask structure and is patterned to expose the Zone 1 features 515 (see FIG. 29). The tantalum layer 505 is then removed from the exposed portion of the mask with a suitable etchant, and the third layer of photoresist 513 is stripped, thus yielding the structure depicted in FIG. 29. In the resulting mask, the Zone 1 features 515 are pure quartz CPL structures with essentially 100% transmission, and the Zone 2 features 517 are tantalum-capped phase shifting quartz structures with 30% transmission. The Zone 3 structures 519 are essentially opaque (0% transmission) chrome-capped structures.

### EXAMPLE 1

This example illustrates the improvement in CD control (for CDs of 60 nm) attainable with the attenuated structures described herein, and as compared to chromeless and chrome-based structures.

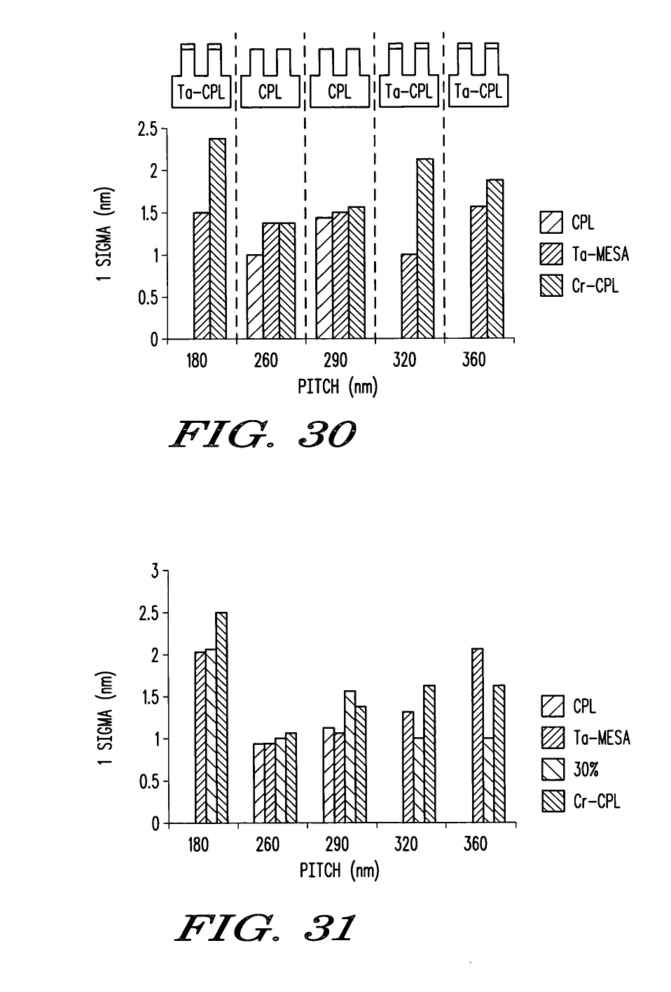

The graph in FIG. 30 illustrates the CD variation (in nanometers) as a function of pitch for Monte Carlo simulation testing of a mask incorporating Zone 2 features made using the methodology described herein (denoted Ta-mesa). For comparison, the CD variation of features made using chrome-capped CPL features (denoted Cr-CPL) and the CD variance of features made using CPL alone (denoted CPL) are also provided at various pitches. The simulation assumed a Ta-mesa structure with a Ta film having a thickness of 90 Å and a transmission of 30% and a phase transmission of 180°. The simulation testing further assumed a full resist model with an exposure tool having QUASAR illumination, and having a numerical aperture of 0.85, a normalized outer radius of 0.87, a normalized inner radius of 0.57, and a 30° opening or pole angle. The simulation also assumes that the process is centered on printing a 60 nm nominal line width with a 260 nm pitch. The standard deviation in dose in the exposure tool (1σ) is assumed to be 1%, the standard deviation in focus (1σ) of the tool is assumed to be 0.04 μm, and the standard deviation in mask critical dimension (6σ, which is essentially the total range) is assumed to be 4 nm (at 1×). The pitch referred to here is the sum of line width and spacing (that is, the spacing between adjacent lines).

As this graph illustrates, the Ta-mesa structures provide CD control that is superior to that of Cr-CPL structures in all of the ranges simulated, and that is somewhat comparable to the CD control provided by CPL at pitches of 260 nm and 290 nm. It is to be noted that CPL does not work at the other pitches simulated under the simulation conditions. It is also to be noted that the CD control provided by the Ta-mesa structures at 320 nm is superior to the CD control provided by CPL structures at 260 nm and 290 nm, while the CD control provided by the Ta-mesa structures at other pitches is at least somewhat comparable to the CD control provided by CPL structures at 260 nm and 290 nm. Hence, these results demonstrate that the Ta-mesa structures are a viable alternative to CPL and Cr-CPL structures under certain conditions and at certain pitches.

### EXAMPLE 2

This example illustrates the improvements in CD control attainable with the attenuated structures described herein (and at CDs of 70 nm), and as compared to chromeless, chrome-based, and prior art attenuated structures.

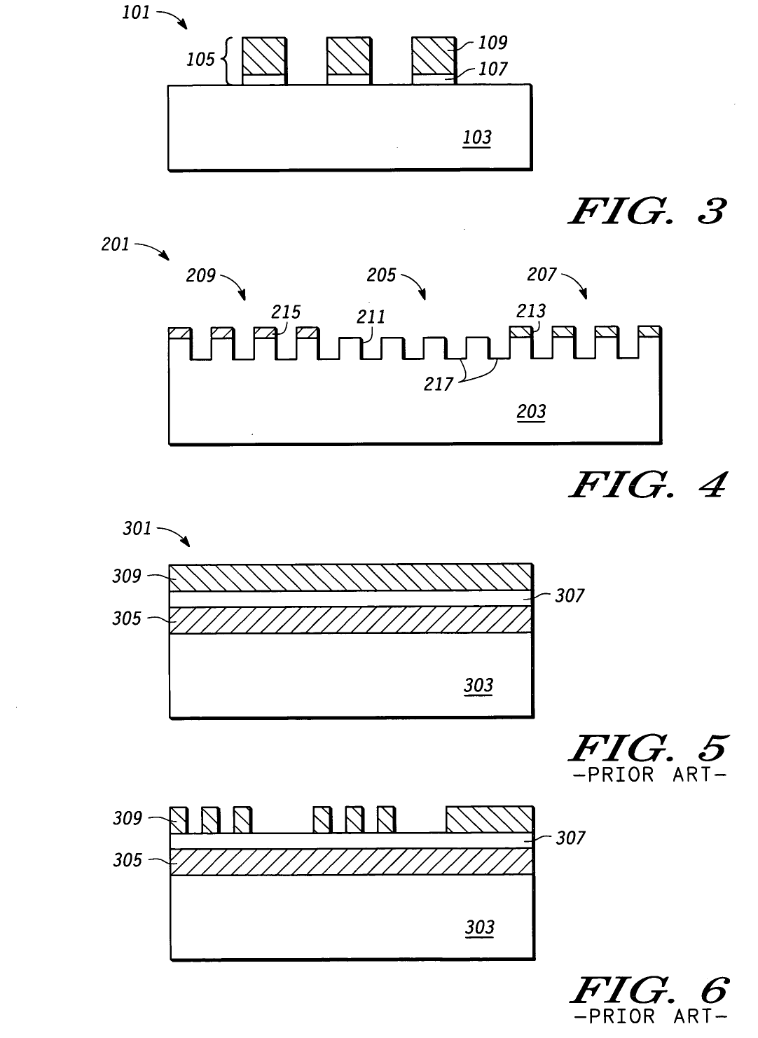

The graph in FIG. 31 illustrates the CD variation (in nanometers) as a function of pitch for Monte Carlo simulation testing of mask features (including Zone 2 features) made using the methodology described herein (denoted Ta-mesa). The simulation also assumes that the process is centered on printing a 70 nm nominal line width with a 260 nm pitch. For comparison, the CD variation of chrome-capped CPL features (denoted Cr-CPL), the CD variation of features made using CPL alone (denoted CPL), and the CD variation of a commercially available material of the type illustrated in FIG. 3 and having a transmission of 30% (denoted 30%) are also provided at various pitches. The remaining conditions and assumptions were the same as in EXAMPLE 1.

As in EXAMPLE 1, the simulation indicated that CPL was not feasible under the simulation conditions at the pitches simulated other than 260 nm and 290 nm. Notably, the Ta-mesa structures were found to provide the same or better CD control to the other structures simulated at 180 nm, 260 nm, and 290 nm. At 320 nm and 360 nm, the 30% structures were found to provide the best CD control, although the Ta-mesa structures outperformed the Cr-CPL structures at 320 nm. Hence, these results demonstrate that the Ta-mesa structures are a viable alternative to CPL, Cr-CPL and 30% structures under certain conditions and at certain pitches.

### EXAMPLE 3

This example illustrates the phase shifting capability of the Ta-mesa structure described in EXAMPLES 1-2.

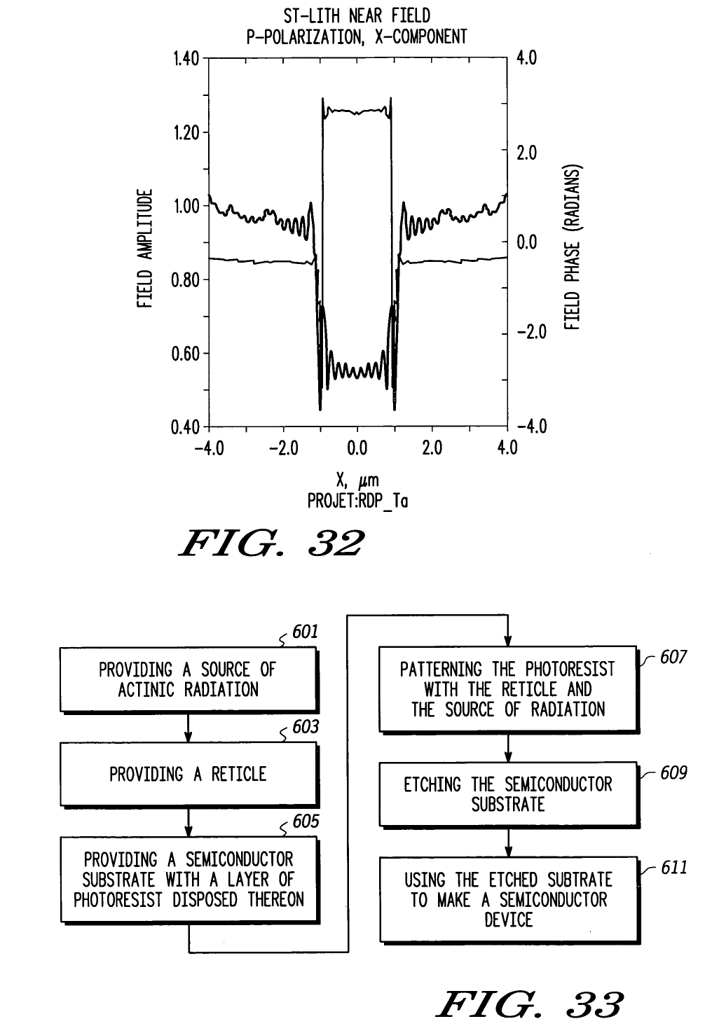

As part of the simulation described in EXAMPLES 1-2, the effect of the Ta-mesa structure on the field amplitude and field phase of the near field actinic radiation was determined. The results are depicted in the graph of FIG. 32, which is a graph of field amplitude and field phase (in radians) as a function of distance (in microns), with the origin centered on the mesa. This graph essentially models the actinic radiation immediately after it passes through the mask, but before it impinges upon the wafer or stepper lens. Graphs of this type provide a useful tool for choosing a material for the capping layer (e.g., layer 213 in FIG. 4) and a quartz etch depth in that they describe all of the vector effects of the actinic radiation as it passes through the mask, including the effective phase change and amplitude (and hence transmission) of the radiation.

As seen from FIG. 32, compared to the radiation passing through the adjacent portion of the mask, the actinic radiation passing through the Ta-mesa structures undergoes a phase shift of about π radians, or 180°, while the amplitude of the actinic radiation drops by about 50%. Hence, these results demonstrate the ability of the Ta-mesa structures to act as phase-shifting, reduced transmission structures.

The use of the reticles described herein in making a semiconductor device may be understood with reference to the flowchart depicted in FIG. 33. As shown therein, such a method will typically involve providing a suitable source of actinic radiation as shown in step 601. As previously noted, common sources of actinic radiation produce wavelengths of 193 nm or 248 nm, although the methods disclosed herein are not particularly limited to a specific wavelength of actinic radiation.

As shown in step 603, a reticle is also provided. Such a reticle is of the type described herein, specific examples of which include the reticles depicted in FIG. 20 and FIG. 29.

As shown in step 605, a semiconductor substrate is then provided which has a layer of photoresist disposed thereon. The layer of photoresist is patterned through the use of the reticle and the source of actinic radiation as shown in step 607. The patterned photoresist is then used as an etch mask to impart the reticle pattern (or a negative thereof) to a substrate, as shown in step 609. The etched substrate is then used to make a semiconductor device, as shown in step 611.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

What is claimed is:

1. A method for making a semiconductor device, comprising:
providing a source of actinic radiation;
providing a reticle comprising (a) a substrate having a plurality of structures defined therein, said substrate being essentially transparent to the actinic radiation, and (b) a layer of attenuating material disposed over at least some of said plurality of structures, wherein the layer of attenuating material has a transmission with respect to the actinic radiation that is within the range of about 5% to about 50%, and wherein the combination of the layer of attenuating material and the substrate imparts to the actinic radiation a phase change within the range of about 165° to about 225°; and
utilizing the reticle and the source of actinic radiation to impart a pattern to a semiconductor substrate.

2. The method of claim 1, wherein the step of utilizing the reticle and the source of actinic radiation to impart a pattern to a semiconductor substrate comprises:
depositing a layer of photoresist over the semiconductor substrate;
imparting a pattern from the reticle to the layer of photoresist through the use of the source of actinic radiation, the pattern exposing a portion of the semiconductor substrate; and
etching the exposed portion of the semiconductor substrate.

3. The method of claim 1, wherein said plurality of structures comprises first and second sets of structures, wherein the first set of structures are phase shifting structures with an attenuating material disposed thereon, and wherein the second set of structures are chromeless phase lithography structures.

4. The method of claim 3, wherein the structures in the first and second sets of structures comprise quartz mesas.

5. The method of claim 4, wherein the first set of structures have about 20% to about 40% transmission of at least one polarization of the actinic radiation, and wherein the second set of chromeless phase lithography structures have greater than about 95% transmission of at least one polarization of the actinic radiation.

6. The method of claim 4, wherein the first set of phase shifting structures have about 25% to about 35% transmission of at least one polarization of the actinic radiation, and wherein the second set of chromeless phase lithography structures have greater than about 95% transmission of at least one polarization of the actinic radiation.

7. The method of claim 3, further comprising a third set of structures, and wherein the third set of structures are essentially opaque to the actinic radiation.

8. The method of claim 1, wherein the substrate has first, second and third sets of structures defined therein, wherein each of the first set of structures are capped with tantalum, and wherein each of the third set of structures are capped with tantalum and chrome.

9. The method of claim 8, wherein the chrome is disposed over the tantalum.

10. The method of claim 8, wherein said second set of structures are pure quartz structures.

11. The method of claim 1, wherein the combination of the layer of attenuating material and the substrate imparts to the actinic radiation a phase change within the range of about 175° to about 215°.

12. The method of claim 1, wherein the combination of the layer of attenuating material and the substrate imparts to the actinic radiation a phase change within the range of about 185° to about 205°.

13. The method of claim 1, wherein the attenuating material comprises tantalum.

14. The method of claim 1, wherein the substrate is a quartz substrate.

15. The method of claim 1, wherein the reticle comprises a first set of reticle features adapted to produce device features having a critical dimension CD within the range of 0<k≦CD<m, where k and m are real number dimensions, wherein the first set of reticle features includes a plurality of phase shifting structures, and wherein the first set of reticle features has a unitary layer of chrome disposed thereon.

16. The method of claim 15, wherein the reticle further comprises a second set of reticle features adapted to produce device features having a critical dimension CD<k, and a third set of reticle features adapted to produce device features having a critical dimension CD≧m.

17. The method of claim 16, wherein 60 nm≦120 nm and 100 nm≦m≦160 nm.

18. The method of claim 16, wherein 80 nm≦k≦100 nm and 120 nm≦m≦140 nm.

19. A method for making a semiconductor device, comprising:
providing a source of actinic radiation;
providing a reticle comprising (a) a first set of reticle features adapted to produce device features having a critical dimension CD within the range of 0<k≦CD<m, (b) a second set of reticle features adapted to produce device features having a critical dimension CD<k, and (c) a third set of reticle features adapted to produce device features having a critical dimension CD≧m, where k and m are real number dimensions, and wherein each of the second set of reticle features comprises a quartz mesa capped with a layer of attenuating material; and
utilizing the reticle and the source of actinic radiation to impart a pattern to a semiconductor substrate.

20. The method of claim 19, wherein the layer of attenuating material has a transmission with respect to the actinic radiation that is within the range of about 5% to about 50%, and wherein the combination of the layer of attenuating material and the substrate imparts to the actinic radiation a phase change within the range of about 165° to about 225°.
